(19) United States
(12) Patent Application Publication
(10) Pub. No.: US 2013/0230652 A1
(43) Pub. Date: Sep. 5, 2013

(54) RUTHENIUM FILM FORMATION METHOD AND COMPUTER READABLE STORAGE MEDIUM

(71) Applicant: TOKYO ELECTRON LIMITED, Minato-ku (JP)

(72) Inventors: Yumiko KAWANO, Nirasaki-shi (JP); Hideaki YAMASAKI, Nirasaki-shi (JP); Susumu ARIMA, Nirasaki-shi (JP)

(73) Assignee: TOKYO ELECTRON LIMITED, Minato-ku (JP)

(21) Appl. No.: 13/862,793

(22) Filed: Apr. 15, 2013

Related U.S. Application Data
(62) Division of application No. 12/192,659, filed on Aug. 15, 2008.
Application No. 12/192,659 is a continuation of application No. PCT/JP07/53577, filed on Feb. 27, 2007.

(30) Foreign Application Priority Data
Feb. 28, 2006 (JP) 2006-053359

(51) Int. Cl. C23C 16/06

(52) U.S. Cl. CPC C23C 16/06
USPC 427/255.28

(57) ABSTRACT

A ruthenium film formation method includes placing and heating a substrate inside a process chamber, and supplying a ruthenium compound gas and a decomposing gas for decomposing this compound into the process chamber while periodically modulating at least one of flow rates of these gases, to form a plurality of steps having gas compositions different from each other. Without purging an interior of the process chamber between these steps, the method includes causing the gases to react with each other on the substrate thus heated, thereby forming a ruthenium film on the substrate.

### CROSS-REFERENCE TO RELATED APPLICATIONS

The present application is a divisional of U.S. application Ser. No. 12/192,659, filed on Aug. 15, 2008, the entire content of which is incorporated herein by reference. U.S. application Ser. No. 12/192,659 is a Continuation Application of PCT Application No. PCT/JP2007/053577, filed Feb. 27, 2007, which was not published under PCT Article 21(2) in English and claims the benefit of priority under 35 U.S.C. 119 from Japanese Application No. 2006-053359 filed Feb. 28, 2006.

### BACKGROUND OF THE INVENTION

1. Field of the Invention

The present invention relates to a ruthenium film formation method for forming a ruthenium film by CVD, and a computer readable storage medium.

2. Description of the Related Art

As regards semiconductor devices, the integration level of integrated circuits is becoming increasingly higher. In this respect, DRAMs are required to have memory cells with a smaller surface area and a larger storage capacity. As capacitors to fulfill this requirement, capacitors having an MIM (metal-insulator-metal) structure have attracted attention. Such capacitors having an MIM structure employ a high dielectric constant material, such as tantalum oxide (Ta₂O₅), to form an insulation film (dielectric film).

Where a high dielectric constant material made of an oxide, such as tantalum oxide, is used to form a dielectric film, a post process, such as a heat process or UV process, is performed thereon to attain a desired dielectric constant. In general, the post process is performed within an atmosphere containing oxygen to prevent oxygen from separating from the oxide material. For this reason, ruthenium has attracted attention as an electrode material, because this metal material cannot be easily oxidized.

On the other hand, in order to increase the storage capacity of DRAMs, capacitors are formed to have an electrode structure of a cylindrical type or stacked type. However, an electrode used in such a structure needs to be laminated on a large step portion created by a preceding process, and so the film formation thereof is required to have good step coverage (the property for covering a step portion). Accordingly, a CVD method is used as the electrode formation method, because it essentially provides high step coverage.

Where a ruthenium film is formed by CVD, conventionally, a cyclopentadienyl compound of ruthenium, such as Ru(EtCp)₂ or Ru(Cp)₂, is used as a source material, along with oxygen gas added thereto. The source material is decomposed on a substrate being heated, so that a ruthenium film is formed by thermal CVD.

However, where the source material described above is used to form a ruthenium film by thermal CVD, there is difficulty in adsorbing the source material on the underlying layer. As a countermeasure to solve this problem, a thin ruthenium seed layer is formed by a PVD method in advance, and a ruthenium film having a predetermined film thickness is then formed thereon by a CVD method (for example, Jpn. Pat. Appln. KOKAI Publication No. 2002-161367).

However, in recent years, the capacitors of DRAMs are increasingly required to have a higher dielectric constant, while a film needs to be formed in a hole with a large aspect ratio such that the opening dimension is as small as 0.5 μm or less and the depth is as large as 2 μm or more. Consequently, there is difficulty in forming the seed layer with good step coverage by a PVD method and in forming a high quality film thereon with good step coverage by a subsequent CVD method.

Further, a ruthenium film of this kind is required to have not only good step coverage but also good film smoothness and low resistivity.

### BRIEF SUMMARY OF THE INVENTION

An object of the present invention is to provide a ruthenium film formation method that can form by CVD a ruthenium film of high quality with good step coverage.

Another object of the present invention is to provide a ruthenium film formation method that can form a ruthenium film with good surface smoothness as well as good step coverage.

Another object of the present invention is to provide a ruthenium film formation method that can form a ruthenium film with low resistivity as well as good step coverage.

Another object of the present invention is to provide a computer readable storage medium that stores a control program for executing one of the methods described above.

According to a first aspect of the present invention, there is provided a ruthenium film formation method comprising: placing and heating a substrate inside a process chamber; supplying gas of a pentadienyl compound of ruthenium and oxygen gas into the process chamber; and causing the gases to react with each other on the substrate thus heated, thereby forming a ruthenium film on the substrate.

The pentadienyl compound of ruthenium may be 2,4-dimethylpentadienyl ethylcyclopentadienyl ruthenium. The method is preferably arranged such that a film formation temperature is set to be 350° C. or more and less than 500° C., and a partial pressure ratio α of the oxygen gas relative to the gas of a pentadienyl compound of ruthenium is set to be 0.01 or more and 3 or less. The method is preferably arranged such that the film formation temperature is set to be 250° C. or more and less than 350° C., and a partial pressure ratio α of the oxygen gas relative to the gas of a pentadienyl compound of ruthenium is set to be 0.01 or more and 20 or less. The method preferably comprises supplying CO into the process chamber in film formation.

The method may be arranged such that a film formation temperature is set to be 250° C. or more and 350° C. or less, and a pressure inside the process chamber is set to be 13.3 Pa or more and 400 Pa or less. In this case, the method is preferably arranged such that the film formation temperature is set to be 280° C. or more and 330° C. or less, and the pressure inside the process chamber is set to be 40 Pa or more and 400 Pa or less.

The method may be arranged such that a pressure inside the process chamber is set to be 6.65 Pa or more and 400 Pa or less, a ratio of a flow rate of a dilution gas for diluting the Ru source gas relative to a flow rate of the Ru source gas is set to be 1.5 or more and 6 or less, and a film formation temperature is set to be 250° C. or more and 350° C. or less. In this case, the method is preferably arranged such that the pressure inside the process chamber is set to be 13.3 Pa or more and 65.5 Pa or less, the ratio of a flow rate of a dilution gas for diluting the Ru source gas relative to a flow rate of the Ru source gas is set to be 2.5 or more and 4.5 or less, and the film formation temperature is set to be 280° C. or more and 330° C. or less.

The method may be arranged such that a film formation temperature is set to be 300° C. or more and 500° C. or less, a pressure is set to be 6.65 Pa or more and 400 Pa or less, and a ratio of a flow rate of a dilution gas relative to a flow rate of the Ru source gas is set to be 2 or more and 10 or less. In this case, the method is preferably arranged such that the film formation temperature is set to be 310° C. or more and 500° C. or less, the pressure is set to be 13.3 Pa or more and 66.5 Pa or less, and the ratio of a flow rate of a dilution gas relative to a flow rate of the Ru source gas is set to be 3 or more and 10 or less.

According to a second aspect of the present invention, there is provided a ruthenium film formation method comprising: placing and heating a substrate inside a process chamber; alternately and repeatedly supplying oxygen gas and gas of a pentadienyl compound of ruthenium into the process chamber with supply of a purge gas interposed therebetween; and causing the gases to react with each other on the substrate thus heated, thereby forming a ruthenium film on the substrate.

In the second aspect, a value of (O₂ gas supply time×O₂ gas partial pressure)/(Ru source gas supply time×Ru source gas partial pressure) is preferably set to be 2 or more and 10 or less. A pressure inside the process chamber is preferably set to be 6.65 Pa or more and 133 Pa or less.

According to a third aspect of the present invention, there is provided a ruthenium film formation method comprising: placing and heating a substrate inside a process chamber; performing a simultaneous supply stage by simultaneously supplying gas of a pentadienyl compound of ruthenium and oxygen gas into the process chamber, and causing the gases to react with each other on the substrate thus heated, thereby forming a ruthenium film; and performing an alternate supply stage by alternately and repeatedly supplying oxygen gas and gas of a pentadienyl compound of ruthenium into the process chamber with supply of a purge gas interposed therebetween, thereby forming a ruthenium film, wherein the ruthenium films formed by the two stages are laminated on the substrate.

In the third aspect, the method may be arranged such that the simultaneous supply stage is first performed, and the alternate supply stage is then performed. Alternatively, the method may be arranged such that the alternate supply stage is first performed, and the simultaneous supply stage is then performed.

According to a fourth aspect of the present invention, there is provided a ruthenium film formation method comprising: placing and heating a substrate inside a process chamber; supplying a ruthenium compound gas and a decomposing gas for decomposing this compound into the process chamber while periodically modulating at least one of flow rates of these gases, to form a plurality of steps having gas compositions different from each other, without purging an interior of the process chamber between these steps; and causing the gases to react with each other on the substrate thus heated, thereby forming a ruthenium film on the substrate.

In the fourth aspect, the method may be arranged such that the plurality of steps comprise a first step of supplying the decomposing gas into the process chamber and a second step of supplying the ruthenium compound gas into the process chamber, and the first and second steps are alternately and repeatedly performed without a step of purging an interior of the process chamber therebetween. The method may be arranged such that the plurality of steps comprise a first step of supplying a gas, which has a composition containing the decomposing gas in a relatively larger amount and the ruthenium compound gas in a relatively smaller amount, into the process chamber and a second step of supplying a gas, which has a composition containing the ruthenium compound gas in a relatively larger amount and the decomposing gas in a relatively smaller amount, into the process chamber, and the first and second steps are alternately and repeatedly performed without a step of purging an interior of the process chamber therebetween. The decomposing gas may be oxygen gas. The ruthenium compound may be a pentadienyl compound of ruthenium.

In the fourth aspect, the method is preferably arranged such that the ruthenium compound is a pentadienyl compound of ruthenium, and the decomposing gas is oxygen gas, and wherein a film formation temperature is set to be 350° C. or more and less than 500° C., and a partial pressure ratio α of the oxygen gas relative to the ruthenium compound gas is set to be 0.01 or more and 3 or less. The method is preferably arranged such that the ruthenium compound is a pentadienyl compound of ruthenium, and the decomposing gas is oxygen gas, and wherein a film formation temperature is set to be 250° C. or more and less than 350° C., and a partial pressure ratio α of the oxygen gas relative to the ruthenium compound gas is set to be 0.01 or more and 20 or less. The pentadienyl compound of ruthenium may be 2,4-dimethylpentadienyl ethylcyclopentadienyl ruthenium. The method preferably comprises supplying CO into the process chamber in film formation.

According to a fifth aspect of the present invention, there is provided a storage medium that stores a program for execution on a computer for controlling a film formation apparatus, wherein the program, when executed, causes the computer to control the film formation apparatus to perform a ruthenium film formation method comprising: placing and heating a substrate inside a process chamber; supplying gas of a pentadienyl compound of ruthenium and oxygen gas into the process chamber; and causing the gases to react with each other on the substrate thus heated, thereby forming a ruthenium film on the substrate.

According to a sixth aspect of the present invention, there is provided a storage medium that stores a program for execution on a computer for controlling a film formation apparatus, wherein the program, when executed, causes the computer to control the film formation apparatus to perform a ruthenium film formation method comprising: placing and heating a substrate inside a process chamber; alternately and repeatedly supplying oxygen gas and gas of a pentadienyl compound of ruthenium into the process chamber with supply of a purge gas interposed therebetween; and causing the gases to react with each other on the substrate thus heated, thereby forming a ruthenium film on the substrate.

According to a seventh aspect of the present invention, there is provided a storage medium that stores a program for execution on a computer for controlling a film formation apparatus, wherein the program, when executed, causes the computer to control the film formation apparatus to perform a ruthenium film formation method comprising: placing and heating a substrate inside a process chamber; supplying a ruthenium compound gas and a decomposing gas for decomposing this compound into the process chamber while periodically modulating at least one of flow rates of these gases, to form a plurality of steps having gas compositions different from each other, without purging an interior of the process chamber between these steps; and causing the gases to react with each other on the substrate thus heated, thereby forming a ruthenium film on the substrate.

According to the present invention, a pentadienyl compound of ruthenium, which is easily decomposable and thus has a good vaporization property, is used as a ruthenium compound. This compound is vaporized and is then caused to react with oxygen gas, wherein the side chain group of the compound is relatively easily removed due to its good decomposition property. Consequently, a ruthenium film can be formed with good surface smoothness as well as good step coverage, without requiring formation of a ruthenium seed layer by PVD. Further, where the temperature, pressure, source material supply are controlled, the step coverage, surface smoothness, film resistivity can be further improved.

Film formation may be performed by supplying a ruthenium compound gas and a decomposing gas for decomposing this compound into the process chamber while periodically modulating at least one of flow rates of these gases, to form a plurality of steps having gas compositions different from each other, without purging an interior of the process chamber between these steps; and causing the gases to react with each other on the substrate thus heated, thereby forming a ruthenium film on the substrate. In this case, it is possible to alternately form a state where ruthenium precipitation tends to be caused and a state where ruthenium precipitation tends to be suppressed, so as to maintain a state in which the rate-determining factor is not dependent on supply, and thereby improve the step coverage.

### BRIEF DESCRIPTION OF THE SEVERAL VIEWS OF THE DRAWING

FIG. 1 is a sectional view schematically showing the structure of a film formation apparatus usable for performing a film formation method according to the present invention.

FIG. 2 is a diagram showing Arrenius plot and incubation time obtained where 2,4-dimethylpentadienyl ethylcyclopentadienyl ruthenium (DER) was used as an Ru source gas and the flow rate ratio of O₂ gas relative to the Ru source was set at different values;

FIG. 3 is a diagram showing the relationship between the temperature and step coverage;

FIG. 4 is a diagram showing the relationship between the pressure and step coverage;

FIG. 5 is a diagram showing the relationship between the Ru film thickness and surface smoothness;

FIG. 6 is a diagram showing the relationship between the film thickness and surface smoothness obtained where the temperature and pressure were set at different values;

FIG. 7 is a diagram showing the relationship between the film thickness and surface smoothness obtained where the flow rate of Ar gas used as a dilution gas was set at different values;

FIG. 8 is a diagram showing the relationship between the film thickness and resistivity obtained where the temperature, pressure, and dilution Ar flow rate were set at different values;

FIG. 9 is a view of a scanning electron microscope (SEM) photograph showing a surface state of an Ru film obtained by a present example 1 according to a first embodiment of the present invention;

FIG. 10 is a view of a scanning electron microscope (SEM) photograph showing step coverage of an Ru film obtained by the present example 1 according to the first embodiment of the present invention;

FIG. 11 is a diagram showing an X-ray diffraction profile of a film obtained by the present example 1 according to the first embodiment of the present invention;

FIG. 12 is a timing chart showing the gas flow sequence of a film formation method according to a second embodiment of the present invention;

FIG. 13 is a diagram showing the relationship between the pressure and surface smoothness obtained by a film formation method according to the second embodiment of the present invention in comparison with a film formation method according to the first embodiment;

FIG. 14 is a timing chart showing the gas flow sequence of a film formation method according to a third embodiment of the present invention;

FIG. 15 is a timing chart showing the gas flow sequence of another film formation method according to the third embodiment of the present invention;

FIG. 16 is a timing chart showing the gas flow sequence of another film formation method according to the third embodiment of the present invention;

FIG. 17 is a timing chart showing the gas flow sequence of a film formation method according to the third embodiment of the present invention;

FIG. 18 is a view of a scanning electron microscope (SEM) photograph showing a surface state of an Ru film obtained by a present example 31 according to the third embodiment of the present invention; and

FIG. 19 is a view of a scanning electron microscope (SEM) photograph showing step coverage of an Ru film obtained by the present example 31 according to the third embodiment of the present invention.

### DETAILED DESCRIPTION OF THE INVENTION

Embodiments of the present invention will now be described with reference to the accompanying drawings.

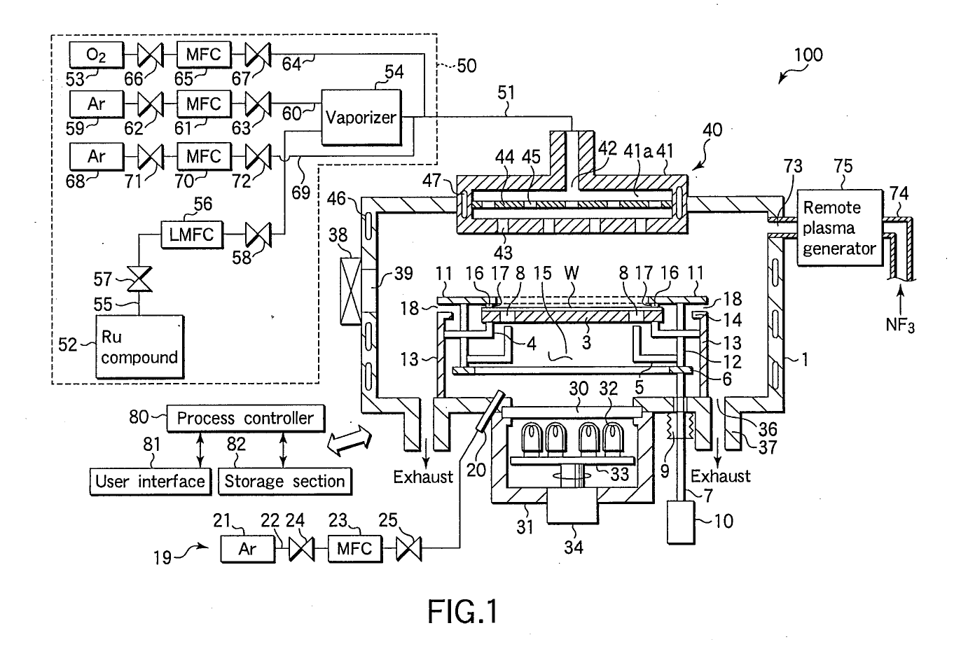

FIG. 1 is a sectional view schematically showing the structure of a film formation apparatus usable for performing a film formation method according to the present invention. The film formation apparatus 100 shown in FIG. 1 includes a cylindrical or box like process chamber 1 made of, e.g., aluminum. A worktable 3 is disposed inside the process chamber 1 to place a target substrate or semiconductor wafer W thereon. For example, the worktable 3 is made of a carbon material or an aluminum compound, such as aluminum nitride, and has a thickness of about 3 mm.

A cylindrical partition wall 13 made of, e.g., aluminum stands on the bottom of the process chamber 1 and surrounds the worktable 3. The partition wall 13 has a bent portion 14 at the top, which is bent in, e.g., a horizontal direction to form an L-shape. The cylindrical partition wall 13 is disposed to form an inactive gas purge space 15 on the backside of the worktable 3. The upper surface of the bent portion 14 is essentially leveled with the upper surface of the worktable 3 and separated from the outer perimeter of the worktable 3 with connecting rods 12 inserted therebetween. The worktable 3 is supported by three support arms 4 (only two of them are shown in FIG. 1) extending from upper portions on the inner side of the partition wall 13.

A plurality of, e.g., three, L-shape lifter pins 5 (only two of them are shown in FIG. 1) are extended upward from a ring support member 6 below the worktable 3. The support member 6 is movable up and down by an elevating rod 7, which penetrates the bottom of the process chamber 1 and is moved up and down by an actuator 10 located below the process chamber 1. The worktable 3 has through holes 8 at positions corresponding to the lifter pins 5, so that lifter pins 5 can project from the through holes 8 to lift up the semiconductor wafer W when the lifter pins 5 are moved up by the actuator 10 through the elevating rod 7 and support member 6. The portion of the process chamber 1 where the elevating rod 7 is inserted is covered with a bellows 9 to prevent outside gas from entering the process chamber 1 through this portion.

A clamp ring member 11 is disposed around the outer perimeter of the worktable 3 to hold and fix the outer peripheral portion of the semiconductor wafer W onto the worktable. For example, the clamp ring member 11 essentially has a ring shape conforming to the contour shape of the circular semiconductor wafer W, and is made of a ceramic, such as aluminum nitride. The clamp ring member 11 is connected to the support member 6 through the connecting rods 12, so that it is moved up and down integratedly with the lifter pins 5. The lifter pins 5 and connecting rods 12 are made of a ceramic, such as alumina.

The clamp ring member 11 has a plurality of contact protrusions 16 arrayed at essentially regular intervals in an annular direction on the lower surface at positions near the inner perimeter. When the semiconductor wafer W is clamped, the lower ends of the contact protrusions 16 come into contact with the upper surface of the outer peripheral portion of the semiconductor wafer W to push it. Each of the contact protrusions 16 has a diameter of about 1 mm and a height of about 50 μm, so that a first gas purge gap 17 having a ring shape is formed at this portion when the semiconductor wafer W is clamped. When the semiconductor wafer W is clamped, the overlap amount of the outer peripheral portion of the semiconductor wafer W with the inner peripheral portion of the clamp ring member 11 (the passage length of the first gas purge gap 17) is about several millimeters.

The outer perimeter of the clamp ring member 11 is located above the top bent portion 14 of the partition wall 13 to form a second gas purge gap 18 having a ring shape therebetween. The second gas purge gap 18 has a width of, e.g., about 500 μm, which is about ten times larger than the width of the first gas purge gap 17. The overlap amount of the peripheral portion of the clamp ring member 11 with the bent portion 14 (the passage length of the second gas purge gap 18) is about ten mm. With this arrangement, an inactive gas can flow out from inside the inactive gas purge space 15 through both of the gaps 17 and 18 into the process space.

The bottom of the process chamber 1 is connected to an inactive gas supply mechanism 19 for supplying an inactive gas into the inactive gas purge space 15. The gas supply mechanism 19 includes a gas nozzle 20 for delivering an inactive gas, such as Ar gas, into the inactive gas purge space 15, an Ar gas supply source 21 for supplying the inactive gas or Ar gas, and a gas line 22 for guiding the Ar gas from the Ar gas supply source 21 to the gas nozzle 20. The gas line 22 is provided with a flow rate controller, such as a mass-flow controller 23, and switching valves 24 and 25. The inactive gas may be He gas in place of Ar gas.

The bottom of the process chamber 1 has a transmission window 30 made of a heat ray transmission material, such as quartz, and airtightly attached thereto at a position directly below the worktable 3. A box like heating chamber 31 is connected to the bottom of the process chamber 1 to surround the transmission window 30 from below. The heating chamber 31 contains a heating device comprising a plurality of heating lamps 32 mounted on a rotary table 33 serving as a reflector as well. The rotary table 33 is rotatable through a rotary shaft by a rotating motor 34 attached to the bottom of the heating chamber 31. Heat rays emitted from the heating lamps 32 are transmitted through the transmission window 30 onto the backside of the worktable 3, so that the worktable 3 is heated.

The bottom of the process chamber 1 has an exhaust port 36 formed near the outer perimeter and connected to a vacuum pump (not shown) through an exhaust line 37. The interior of the process chamber 1 can be set at a predetermined vacuum level when it is exhausted by the pump through the exhaust port 36 and exhaust line 37. The process chamber 1 has a transfer port 39 formed in the sidewall and provided with a gate valve 38 for opening/closing the transfer port 39, so that the semiconductor wafer W is transferred through the transfer port 39.

On the other hand, a showerhead 40 for supplying a source gas and so forth into the process chamber 1 is disposed on the ceiling of the process chamber 1 to face the worktable 3. The showerhead 40 includes a disk-like head main body 41 made of, e.g., aluminum and having an inner space 41a. The head main body 41 has a gas feed port 42 at the ceiling. The gas feed port 42 is connected through a line 51 to a process gas supply mechanism 50 for supplying process gases necessary for forming an ruthenium (Ru) film. The head main body 41 has a number of gas spouting holes 43 formed all over the bottom, so that a gas supplied into the head main body 41 is delivered through the holes 43 to the entire surface of the semiconductor wafer W in the process space inside the process chamber 1. The space 41a inside the head main body 41 is provided with a distribution plate 44 disposed therein and having a number of gas distribution holes 45, so that a gas is uniformly supplied onto the surface of the semiconductor wafer W. Further, the sidewall of the process chamber 1 and the sidewall of the showerhead 40 are provided with cartridge heaters 46 and 47 built therein to adjust the temperature, so that the sidewalls and showerhead portions can be maintained at a predetermined temperature while they are in contact with the gas.

The process gas supply mechanism 50 includes an Ru compound supply source 52 that stores a liquid ruthenium (Ru) compound, an oxygen gas supply source 53 for supplying oxygen gas (O₂ gas), and a vaporizer 54 for vaporizing the Ru compound. The Ru compound supply source 52 is connected to the vaporizer 54 through a line 55, so that the liquid Ru compound can be supplied from the Ru compound supply source 52 to the vaporizer 54 by use of, e.g., a pressurized gas or pump. The line 55 is provided with a flow rate controller, such as a liquid mass-flow controller (LMFC) 56, and switching valves 57 and 58 one on either sides of the LMFC 56. The vaporizer 54 is connected to the showerhead 40 through the line 51. Pentadienyl compound is used as the Ru compound. The pentadienyl compound is preferably exemplified by 2,4-dimethylpentadienyl ethylcyclopentadienyl ruthenium. The vaporizer 54 is connected to an Ar gas supply source 59 for supplying Ar gas used as a carrier gas (carrier Ar) through a line 60. The Ar gas used as a carrier gas is supplied to the vaporizer 54, while the interior of the vaporizer 54 is heated to, e.g., 60 to 180° C., so that the vaporized Ru compound is fed through the line 51 and showerhead 40 into the process chamber 1. The line 60 is provided with a flow rate controller, such as a mass-flow controller (MFC) 61, and switching valves 62 and 63 one on either sides of the MFC 61. The oxygen gas supply source 53 is connected to the line 51 through a line 64, so that the oxygen gas can be fed from the line 64 through the line 51 and showerhead 40 into the process chamber 1. The line 64 is provided with a flow rate controller, such as a mass-flow controller (MFC) 65, and switching valves 66 and 67 one on either sides of the MFC 65. The gas supply mechanism 50 further includes an Ar gas supply source 68 for supplying dilution argon gas used for diluting gas inside the process chamber 1. The Ar gas supply source 68 is connected to the line 51 through a line 69, so that the dilution argon gas can be fed from the line 69 through the line 51 and showerhead 40 into the process chamber 1. The line 69 is provided with a flow rate controller, such as a mass-flow controller (MFC) 70, and switching valves 71 and 72 one on either sides of the MFC 70.

The sidewall of the process chamber 1 has a cleaning gas feed portion 73 at an upper position for feeding NF₃ gas as a cleaning gas. The cleaning gas feed portion 73 is connected to a line 74 for supplying NF₃ gas, which is provided with a remote plasma generator 75. NF₃ gas flowing through the line 74 is turned into plasma in the remote plasma generator 75, and is supplied into the process chamber 1, when cleaning is performed inside the process chamber 1. A remote plasma generator may be disposed directly above the showerhead 40, so that cleaning gas is supplied through the showerhead 40. Without using the remote plasma, plasma-less thermal cleaning using, e.g., ClF₃ may be performed.

The respective components of the film formation apparatus 100 are connected to and controlled by a process controller 80 comprising a computer. The process controller 80 is connected to the user interface 81, which includes, e.g., a keyboard and a display, wherein the keyboard is used for a process operator to input commands for operating the film formation apparatus 100, and the display is used for showing visualized images of the operational status of the film formation apparatus 100. Further, the process controller 80 is connected to a storage section 82 that stores recipes, i.e., control programs for the process controller 80 to control the film formation apparatus 100 so as to perform various processes, and programs for the respective components of the film formation apparatus 100 to perform processes in accordance with process conditions. The recipes may be stored in a hard disk or semiconductor memory, or stored in a storage medium of the portable type, such as a CDROM or DVD. Alternatively, the recipes may be used online while they are transmitted from another apparatus through, e.g., a dedicated line, as needed. A required recipe is retrieved from the storage section 82 and executed by the process controller 80 in accordance with an instruction or the like input through the user interface 81. Consequently, the film formation apparatus 100 can perform a predetermined process under the control of the process controller 80.

Next, an explanation will be given of a film formation method according to an embodiment of the present invention performed in the film formation apparatus having the structure described above.

### First Embodiment

At first, the gate valve 38 is opened, and a semiconductor wafer W is loaded through the transfer port 39 into the process chamber 1 and placed on the worktable 3. The semiconductor wafer W is heated by the worktable 3, which has been heated by heat rays emitted from the heating lamps 32 and transmitted through the transmission window 30. Then, the interior of the process chamber 1 is vacuum-exhausted by the vacuum pump (not shown) through the exhaust port 36 and exhaust line 37, to set the pressure inside the process chamber 1 at about 1 to 500 Pa. Further, at this time, the semiconductor wafer W is heated to a temperature of, e.g., 200 to 500° C.

Then, the valves 57 and 58 are opened, so that an Ru compound used as an Ru source, such as a pentadienyl compound of Ru, e.g., 2,4-dimethylpentadienyl ethylcyclopentadienyl ruthenium, is supplied into the vaporizer 54, while its flow rate is controlled by the liquid mass-flow controller 56. Further, the valves 62 and 63 are opened, so that Ar gas used as a carrier gas is supplied from the Ar gas supply source 59 into the vaporizer 54. With the operations described above, vapor of the pentadienyl compound of Ru is supplied through the showerhead 40 into the process chamber 1. At the same time, valves 66, 67, 71, and 72 are opened, so that oxygen gas used as a reaction gas and Ar gas used as a dilution gas are supplied from the oxygen gas supply source 53 and Ar gas supply source 68 through the showerhead 40 into the process chamber 1, while their flow rates are respectively controlled by the mass-flow controllers 65 and 70. Consequently, a ruthenium film is formed on the surface of the semiconductor wafer W.

During this film formation, Ar gas is supplied at predetermined flow rate from the gas nozzle 20 of the inactive gas supply mechanism 19 disposed below the worktable 3 into the inactive gas purge space 15. The pressure of this Ar gas is set to be slightly higher than the pressure inside the process space, so that the Ar gas slowly flows into the process space located on the upper side through the first gas purge gap 17 having a width of about 50 μm and the second gas purge gap 18 having a width of about 500 μm.

In this case, since the Ru source gas or oxygen gas cannot enter the inactive gas purge space 15, a ruthenium film is prevented from being unnecessarily deposited on the edge side and back side of the semiconductor wafer W and the surface of the worktable 3.

The pentadienyl compound of Ru used here includes a pentadienyl of the straight chain type, and has a lower melting point than a cyclopentadienyl compound formed of a cyclopentadienyl ring conventionally used. In other words, this is an organic Ru compound easily decomposable and thus has a good vaporization property with a melting point of 25° C. or less and decomposition starting temperature of 180° C. or more. Such a compound is typically exemplified by 2,4-dimethylpentadienyl ethylcyclopentadienyl ruthenium. When this compound is supplied along with oxygen gas and reacts with the oxygen gas, the side chain group of the compound is relatively easily removed due to its good decomposition property. Consequently, a ruthenium film can be formed with good surface smoothness as well as good step coverage, without requiring formation of a ruthenium seed layer by PVD.

An Ru source using such a pentadienyl compound is disclosed in Jpn. Pat. Appln. KOKAI Publication No. 2003-342286, in which the Ru source is used as a CVD film formation gas as in the present invention. However, this publication merely discloses that “an RuO₂ film is formed where oxygen gas is added to this Ru source” (paragraph 0060 of the publication), and does not at all disclose that “oxygen gas is added to a pentadienyl compound of Ru to form an Ru film with good surface smoothness as well as good step coverage”, which corresponds to the arrangement and effect of the present invention. Accordingly, the technique disclosed in this publication completely differs from the technique of the present invention.

According to the first embodiment of the present invention, as described above, a pentadienyl compound of Ru, oxygen gas, and a dilution gas (Ar gas) are supplied into the process chamber 1 to form an Ru film. In this process, the rate-determining domain of the surface reaction significantly changes, depending on the partial pressure ratio between the Ru source and oxygen gas. Accordingly, the step coverage and surface smoothness can be improved by suitably controlling the partial pressure ratio between the Ru source and oxygen gas.

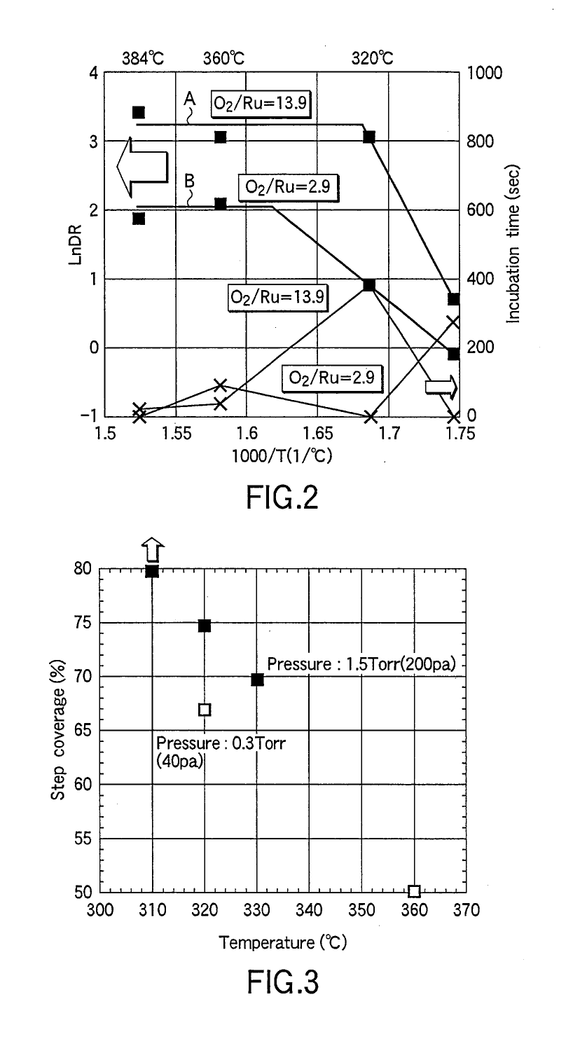

This matter will be explained with reference to FIG. 2. FIG. 2 is a diagram showing Arrenius plot and incubation time obtained where 2,4-dimethylpentadienyl ethylcyclopentadienyl ruthenium (DER) was used as an Ru source gas and the flow rate ratio of O₂ gas relative to the Ru source was set at different values. The flow rate ratio of O₂ gas relative to the Ru source corresponds to the partial pressure ratio thereof. In the Arrenius plot, a domain with an inclined straight line is a reaction-dependent rate-determining domain, and a domain with a line parallel with the X axis is a supply-dependent rate-determining domain. In the supply-dependent rate-determining domain, the Ru source gas or O₂ gas supplied onto the wafer is consumed by the reaction near the wafer surface and thus tends to be not supplied into holes, and so the reaction proceeds only on the surface and results in poor step coverage. In the reaction-dependent rate-determining domain, the Ru source and O₂ gas supplied onto the wafer are not consumed by the reaction near the wafer surface but are sufficiently supplied into holes, thereby providing good step coverage. Accordingly, the reaction-dependent rate-determining domain is preferable, and, as shown in FIG. 2, the reaction-dependent rate-determining domain is apt to appear where the film formation temperature is lower. However, as the film formation temperature is lower, the incubation time becomes longer. Accordingly, in order to obtain good step coverage, the flow rate ratio of O₂ gas/Ru source gas, i.e., the partial pressure ratio α of O₂ gas/Ru source gas is preferably set at a low value, so as not to fall in an Ru supply-dependent rate-determining state. Alternatively, in order to obtain good step coverage, the film formation temperature is set to be low, while the flow rate ratio of O₂ gas/Ru source gas, i.e., the partial pressure ratio α of O₂ gas/Ru source gas is set at a high value, so as not to prolong the incubation time too much. In light of these matters, it is preferable that the film formation temperature is set to be 350° C. or more and less than 500° C. and the partial pressure ratio α of O₂ gas/Ru source gas is set to be 0.01 or more and 3 or less, or that the film formation temperature is set to be 250° C. or more and less than 350° C. and the partial pressure ratio α of O₂ gas/Ru source gas is set to be 0.01 or more and 20 or less.

In order to further improve the step coverage, it is preferable that the film formation temperature is set to be 250° C. or more and 350° C. or less and the pressure inside the process chamber 1 is set to be 13.3 Pa (0.1 Torr) or more and 400 Pa (3 Torr) or less. Where the temperature is set to be 250° C. or more and 350° C. or less, a reaction-dependent rate-determining state can be easily obtained to supply the Ru source and O₂ gas into holes. In addition, where the pressure inside the process chamber 1 is set at a higher pressure of 13.3 Pa (0.1 Torr) or more and 400 Pa (3 Torr) or less, the probability of the reaction between the Ru source and O₂ gas inside holes is higher. Consequently, these ranges bring about good step coverage. More preferably, the temperature is set to be 280° C. or more and 330° C. or less, and the pressure is set to be 40 Pa (0.3 Torr) or more and 400 Pa (3 Torr) or less.

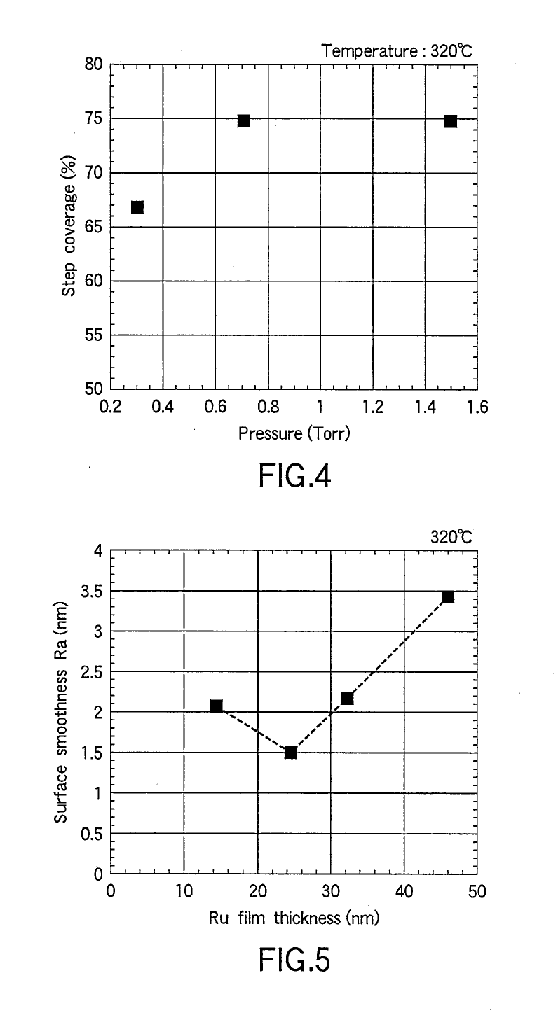

This matter is shown in FIGS. 3 and 4, in which 2,4-dimethylpentadienyl ethylcyclopentadienyl ruthenium (DER) was used as an Ru source gas. FIG. 3 is a diagram showing changes in the step coverage relative to the temperature. FIG. 4 is a diagram showing changes in the step coverage relative to the pressure. Further, another condition was set to be Ru source gas/O₂/carrier Ar/dilution Ar=33/50/103/122 (mL/min (sccm)). As shown in FIGS. 3 and 4, it has been found that, with a decrease in the temperature or an increase in the pressure, the step coverage tends to be better. Further, the step coverage is improved within the ranges described above, and particularly the step coverage is imporoved by 65% or more under a temperature of 330° C. or less and a pressure of 0.3 Torr (40 Pa) or more.

Where an Ru film is formed by a reaction between the Ru source and O₂ gas, CO gas is preferably further added to control the step coverage. Where CO acts on Ru formed by a reaction of O₂ with the compound described above used as the Ru source, the CO retards the reaction between the Ru compound and O₂ by means of evaporation in the form of an Ru—CO compound or the like. Accordingly, the step coverage of the Ru film can be controlled by adjusting the flow rate of CO gas. In other words, where CO gas is suitably added, the step coverage is improved. In this respect, the flow rate of CO gas is preferably set to be 10 mL/min (sccm) or more and 100 mL/min (sccm) or less.

Incidentally, source materials of this kind have difficulty in generation of initial nuclei for film formation, and may thereby deteriorate the film smoothness due to a long incubation time and rough and large crystal grains, depending on the conditions. In order to solve this problem concerning the surface smoothness, the film formation process is preferably arranged to suitably adjust the pressure inside the process chamber, the flow rate of a dilution gas (for example, Ar gas) for diluting the Ru source gas, and the film formation temperature. Specifically, the pressure is preferably set to be 6.65 Pa (0.05 Torr) or more and 400 Pa (3 Torr) or less, the ratio of dilution gas flow rate/Ru source gas flow rate is preferably set to be 1.5 or more and 6 or less, and the film formation temperature is preferably set to be 250° C. or more and 350° C. or less. If the pressure is too high, rough grains can easily grow and deteriorate the smoothness. If the pressure is too low, the Ru gas can hardly reach the bottom of holes and thus cannot maintain the necessary step coverage. If the dilution gas flow rate is too low, the Ru source gas partial pressure becomes substantially high and rough grains can thereby easily grow. If the dilution gas flow rate is too high, there is brought about difficulty in generation of initial nuclei for film formation, and the film thereby becomes nondense. Further, if the temperature is too high, rough grains can also easily grow.

The pressure is more preferably set to be 13.3 Pa (0.1 Torr) or more and 66.5 Pa (0.5 Torr) or less. The ratio of dilution gas flow rate/Ru source gas flow rate is more preferably set to be 2.5 or more and 4.5 or less. The film formation temperature is more preferably set to be 280° C. or more and 330° C. or less.

The film surface smoothness also depends on the film thickness. Specifically, as the film thickness is smaller, the smoothness is more improved, but, if it is too small, the smoothness is deteriorated again. Specifically, this relationship is shown in FIG. 5. FIG. 5 is a diagram showing the relationship between the film thickness and surface smoothness (Ra) obtained where 2,4-dimethylpentadienyl ethylcyclopentadienyl ruthenium (DER) was used as an Ru source gas and the Ru film thickness was set at different values by adjusting the pressure and film formation method. As shown in FIG. 5, the smoothness takes on a minimum value at a film thickness near 25 nm. Since a value of the film thickness to obtain the minimum value of Ra can be shifted by adjusting a process condition, it is necessary to adjust the process conditions to obtain the minimum value of Ra along with a desired film thickness.

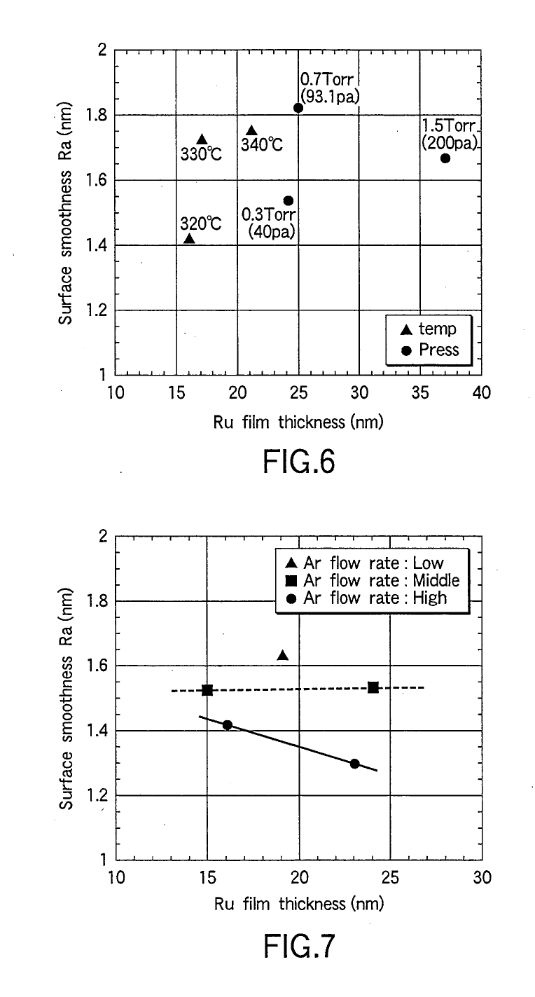

FIG. 6 is a diagram showing the relationship between the film thickness and surface smoothness obtained where 2,4-dimethylpentadienyl ethylcyclopentadienyl ruthenium (DER) was used as an Ru source gas and the temperature and pressure were set at different values. In FIG. 6, the horizontal axis denotes the film thickness while the vertical axis denotes the surface smoothness. Further, another condition was set to be Ru source gas/O₂/carrier Ar/dilution Ar=33/50/103/122 (mL/min (sccm)). As shown in FIG. 6, the surface smoothness is good at a pressure of 0.3 Torr (40 Pa), but is becomes poor to some extent at a pressure over 0.5 Torr (66.5 Pa). As regards the film formation temperature, as the temperature is higher, the smoothness is poorer.

FIG. 7 is a diagram showing the relationship between the film thickness and surface smoothness obtained where 2,4-dimethylpentadienyl ethylcyclopentadienyl ruthenium (DER) was used as an Ru source gas and the flow rate of Ar gas used as a dilution gas was set at different values. In FIG. 7, the horizontal axis denotes the film thickness while the vertical axis denotes the surface smoothness. Further, the temperature was set at 320° C. and the pressure was set at 0.3 Torr (40 Pa). In FIG. 7, the low value of the Ar flow rate is 48 mL/min (sccm), the middle value of the Ar flow rate is 122 mL/min (sccm), and the high value of the Ar flow rate is 204 mL/min (sccm). As shown in FIG. 7, the surface smoothness is good as long as the flow rate of Ar used as a dilution gas is appropriate.

In addition to the properties described above, the Ru film is required to have a relatively low resistivity. However, in a domain with a low film formation temperature and good step coverage, the resistivity tends to be higher. In light of this, in order to attain a preferable resistivity while maintaining the coverage at a certain level, the film formation temperature is preferably set to be 300° C. or more and 500° C. or less, the pressure is preferably set to be 6.65 Pa (0.05 Torr) or more and 400 Pa (3 Torr) or less, and the ratio of dilution gas flow rate/Ru source gas flow rate is preferably set to be 2 or more and 10 or less. If the film formation temperature is lower than the range described above, non-reacted parts of the Ru source can easily remain and increase the resistivity. If the film formation temperature is higher than the range described above, the step coverage tends to be poor. If the pressure is higher than the range described above, by-product impurities tend to be insufficiently removed by evaporation from the film formation growth surface, and thereby increase the resistivity. If the pressure is lower than the range described above, the step coverage tends to be poor. Further, if the dilution gas flow rate is lower than the range described above, by-products tend to be insufficiently removed by evaporation from the film formation growth surface, and thereby increase the resistivity. If the dilution gas flow rate is higher than the range described above, there is brought about difficulty in generation of initial nuclei for film formation, and the film thereby becomes nondense.

The film formation temperature is more preferably set to be 310° C. or more and 500° C. or less. The pressure is more preferably set to be 13.3 Pa (0.1 Torr) or more and 66.5 Pa (0.5 Torr) or less. The ratio of dilution gas flow rate/Ru source gas flow rate is more preferably set to be 3 or more and 10 or less.

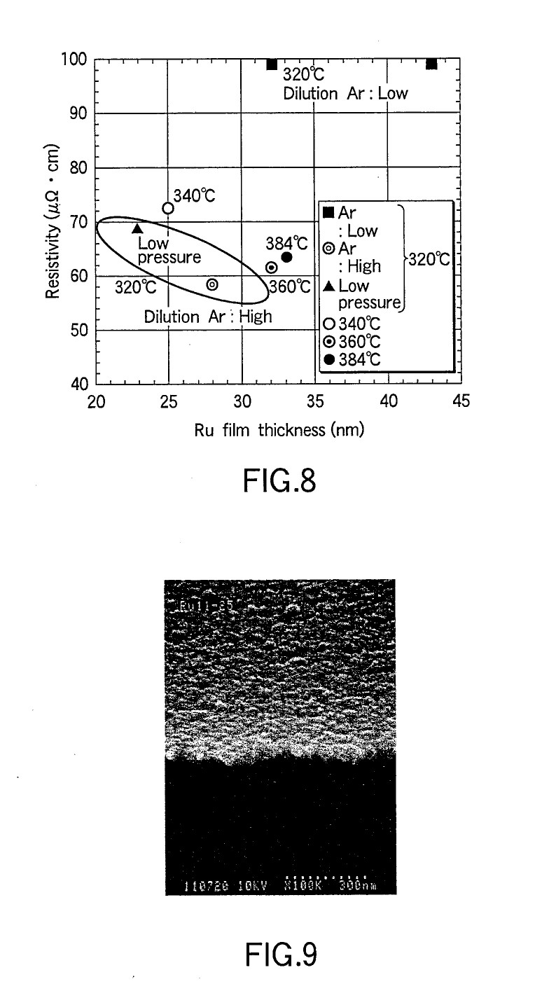

FIG. 8 is a diagram showing the relationship between the film thickness and resistivity obtained where 2,4-dimethylpentadienyl ethylcyclopentadienyl ruthenium (DER) was used as an Ru source gas and the temperature, pressure, dilution Ar flow rate were set at different values, while the basic conditions were set to include the flow rates of Ru source gas/O₂/carrier Ar/dilution Ar=33/50/102/122 (mL/min (sccm)) and the pressure=0.3 Torr. In FIG. 8, the horizontal axis denotes the film thickness while the vertical axis denotes the resistivity. The low value of the dilution Ar is 48 mL/min (sccm) and the high value of the dilution Ar is 204 mL/min (sccm). Further, the low pressure is 0.15 Torr. As shown in FIG. 8, the resistivity is greatly influenced by the film formation temperature such that the resistivity is lower as the temperature is higher as in 340° C. or more. However, even where the temperature is as low as 320° C., the resistivity can be lower by setting the pressure to be lower or setting the dilution Ar flow rate to be higher. As regards the influence of the dilution Ar flow rate, the resistivity becomes extremely high where the dilution Ar flow rate ratio is lower than 100 mL/min (sccm). Where the temperature, pressure, and dilution Ar flow rate are set to be within the ranges described above, the resistivity is present within a permissible range.

After the film formation process is performed as described above, the gate valve 38 is opened, and the semiconductor wafer W processed by the film formation is unloaded. After the film formation process is performed on a predetermined number of semiconductor wafers W, cleaning is performed inside the process chamber 1. At this time, NF₃ is supplied through the line 74 into the remote plasma generator 75 and is turned into plasma therein, and is further supplied into the process chamber 1 to perform plasma cleaning inside the process chamber 1.

Next, an explanation will be given of present examples along with comparative examples, where film formation was actually performed in accordance with the first embodiment.

### Present Example 1

In the apparatus shown in FIG. 1, the lamp power was adjusted to set the temperature of the worktable at a film formation temperature of 384° C., and a 200-mm Si wafer was loaded by a transfer robot into the process chamber to form an Ru film. The Ru source was 2,4-dimethylpentadienyl ethylcyclopentadienyl ruthenium. The 2,4-dimethylpentadienyl ethylcyclopentadienyl ruthenium was supplied from the mother tank (Ru compound supply source) 52 at a controlled flow rate through the liquid mass-flow controller (LMFC) 56 into the vaporizer 54 set at a temperature of 120° C. Then, it was vaporized by use of an Ar gas as a carrier gas in the vaporizer 54, and the vapor thus generated was supplied through the showerhead 40 into the process chamber 1. Further, dilution Ar gas for diluting gas inside the process chamber, backside Ar gas for preventing gas from flowing around onto the backside of the wafer, and O₂ gas to react with the Ru source were supplied as other gases, as described above. The conditions used at this time were set as follows.

Worktable temperature: 384° C.,

Pressure inside process chamber: 40 Pa,

Carrier Ar flow rate: 100 mL/min,

Dilution Ar flow rate: 144 mL/min,

Backside Ar flow rate: 100 mL/min,

Ru source flow rate: 38 mL/min,

O₂ flow rate: 50 mL/min, and

(Hereinafter, the flow rate is denoted as a value converted into the normal state (sccm).)

Film formation time: 200 sec.

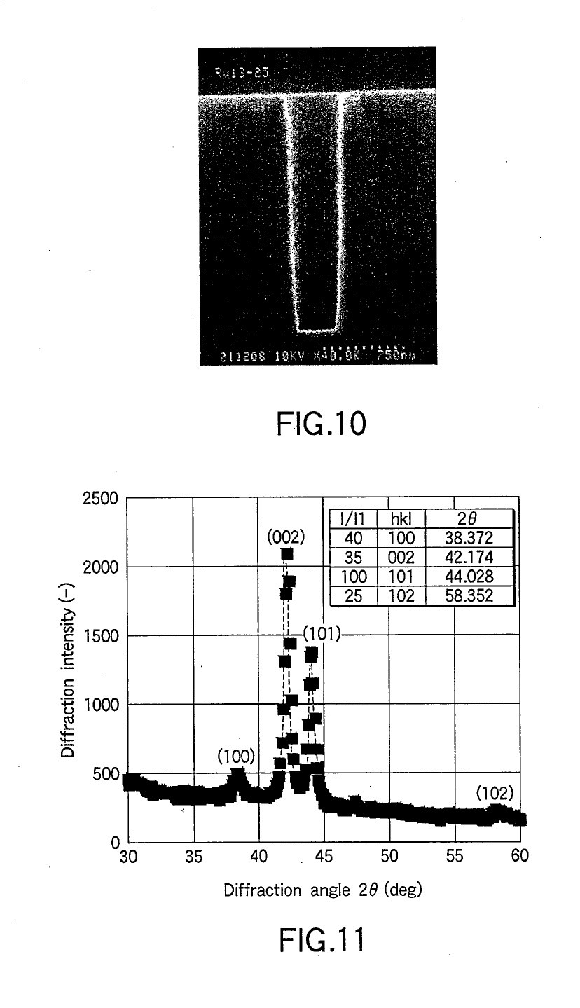

The Ru film thus formed had a thickness of 65.2 nm and a resistivity of 15.7 μΩ·cm. The surface state of the film was smooth, as shown in the scanning electron microscope (SEM) photograph of FIG. 9. Then, film formation was performed for 400 sec under the same conditions on a chip wafer with a hole pattern having a diameter of 0.5 μm and a depth of 2.2 μm. Consequently, the step coverage was as good as 80%, as shown in the SEM photograph of FIG. 10. Further, the film thus formed was examined by X-ray diffraction to identify the material. Consequently, formation of an Ru film was confirmed, as shown in FIG. 11.

### Comparative Example 1

An Ru film was formed by the same method as the present example 1 except that the Ru source was Ru(ETCp)₂ and the conditions were set as follows.

Worktable temperature: 300° C.,

Pressure inside process chamber: 133 Pa,

Carrier Ar flow rate: 100 mL/min (sccm),

Dilution Ar flow rate: 0 mL/min (sccm),

Backside Ar: 100 mL/min (sccm),

Ru source flow rate: 7.8 mL/min (sccm),

O₂ gas flow rate: 500 mL/min (sccm), and

Film formation time: 272 sec.

The Ru film thus formed had a thickness of 140 nm and a very rough surface like as Ru metal generated by a vapor phase reaction between the Ru source and O₂ gas lay thick. Further, the film was examined by a tape test in terms of its adhesiveness, and found that it was easily peeled off without using a notch.

### Present Examples 2 to 18

In order to examine the preferable ranges described above set to improve the step coverage, surface smoothness, and film resistivity, experiments were conducted while the film formation temperature, pressure, dilution Ar gas flow rate, and film formation time were set at different values. Conditions used in these experiments are shown in Table 1 in detail. The value of the step coverage was calculated by a formula of ([Ru film thickness at hole bottom]/[Ru film thickness at hole top surface])×100%, where an Ru film was formed in a hole pattern having a diameter of 0.1 μm and a depth of 6 μm.

In present examples 2 to 5 that satisfied conditions for obtaining preferable step coverage, i.e., where the film formation temperature was set to be 250° C. or more and 350° C. or less and the pressure was set to be 13.3 Pa (0.1 Torr) or more and 400 Pa (3 Torr) or less, the step coverage was as good as 70% or more. In a present example 6 where the film formation temperature was set at 360° C., the step coverage was 50%, which was lower than those of the present examples 2 to 5.

In present examples 7 to 11 that satisfied conditions for obtaining preferable surface smoothness, i.e., where the pressure was set to be 6.65 Pa (0.05 Torr) or more and 400 Pa (3 Torr) or less, the ratio of dilution gas flow rate/Ru source gas flow rate was set to be 1.5 or more and 6 or less, and the film formation temperature was set to be 250° C. or more and 350° C. or less, the smoothness Ra took on a value of lower than 2 nm. Of them, in the present examples 7 and 8 that satisfied the more preferable range, the smoothness was particularly good. On the other hand, in the present examples 12 and 13 that were out of the preferably range described above, the smoothness Ra took on a value of higher than 2 nm.

Further, in present examples 14 to 16 that satisfied conditions for obtaining preferable resistivity, i.e., where the film formation temperature was set to be 300° C. or more and 500° C. or less, the pressure was set to be 6.65 Pa (0.05 Torr) or more and 400 Pa (3 Torr) or less, and the ratio of dilution gas flow rate/Ru source gas flow rate was set to be 2 or more and 10 or less, the resistivity took on a relatively good value of lower than 100 μΩ·cm. Of them, in the examples 14 and 15 that satisfied the more preferable range, the resistivity took on a particularly good value of lower than 70 μΩ·cm. On the other hand, in present examples 17 and 18 that were out of the preferably range described above, the resistivity took on a value of higher than 100 μΩ·cm.

TABLE 1

| | Film | | | Carrier | | Dilution | | | | | | |
|---|---|---|---|---|---|---|---|---|---|---|---|---|
| | formation | | Ru source | Ar flow | O₂ flow | Ar flow | | Film | | | | |
| | temperature | Pressure | flow rate | rate | rate | rate | Time | thickness | Resistivity | Ra | Coverage | |
| | (° C.) | (Torr) | (g/min) | (sccm) | (sccm) | (sccm) | (sec) | (nm) | (μΩ · cm) | (nm) | (%) | Remarks |
| Present example 2 | 320 | 0.7 | 0.1 | 102 | 50 | 122 | 1800 | | | | 75 | Coverage |
| Present example 3 | 320 | 1.5 | 0.1 | 102 | 50 | 122 | 900 | | | | 75 | |
| Present example 4 | 310 | 1.5 | 0.1 | 102 | 50 | 122 | 600 | | | | >80 | |
| Present example 5 | 330 | 1.5 | 0.1 | 102 | 50 | 122 | 600 | | | | 70 | |
| Present example 6 | 360 | 0.3 | 0.1 | 102 | 50 | 122 | 600 | | | | 50 | |
| Present example 7 | 320 | 0.3 | 0.1 | 100 | 50 | 48 | 900 | 24 | | 1.54 | 65 | Smoothness |
| Present example 8 | 320 | 0.3 | 0.1 | 100 | 55 | 122 | 600 | 23 | | 1.3 | 65 | |
| Present example 9 | 340 | 0.3 | 0.1 | 103 | 55 | 122 | 400 | 21 | | 1.75 | 60 | |
| Present example 10 | 320 | 0.3 | 0.1 | 103 | 55 | 204 | 600 | 19 | | 1.64 | 63 | |
| Present example 11 | 320 | 0.7 | 0.1 | 103 | 55 | 48 | 600 | 25 | | 1.82 | 75 | |
| Present example 12 | 384 | 0.3 | 0.1 | 103 | 55 | 122 | 120 | 24 | | 2.2 | — | |
| Present example 13 | 320 | 0.3 | 0.1 | 103 | 55 | 400 | 900 | 14 | | 2.05 | 62 | |
| Present example 14 | 320 | 0.3 | 0.1 | 103 | 55 | 48 | | 23 | 69.1 | | 65 | Resistivity |
| Present example 15 | 360 | 0.3 | 0.1 | 103 | 55 | 48 | | | 61.8 | | 50 | |
| Present example 16 | 320 | 0.3 | 0.1 | 100 | 50 | 48 | | 32 | 99 | | 65 | |
| Present example 17 | 280 | 0.3 | 0.1 | 103 | 55 | 122 | 1800 | 20 | 122 | | 70 | |
| Present example 18 | 320 | 1.5 | 0.1 | 103 | 55 | 122 | 300 | 25 | 113 | | 75 | |

### Second Embodiment

In this embodiment, an explanation will be given of a case where an Ru film is formed by alternate supply similar to a so-called ALD method.

At first, as in the first embodiment, the gate valve 38 is opened, and a semiconductor wafer W is loaded through the transfer port 39 into the process chamber 1 and placed on the worktable 3. The semiconductor wafer W is heated by the worktable 3, which has been heated by heat rays emitted from the heating lamps 32 and transmitted through the transmission window 30. Then, the interior of the process chamber 1 is vacuum-exhausted by the vacuum pump (not shown) through the exhaust port 36 and exhaust line 37, to set the pressure inside the process chamber 1 at about 1 to 500 Pa. Further, at this time, the semiconductor wafer W is heated to a temperature of, e.g., 200 to 500° C.

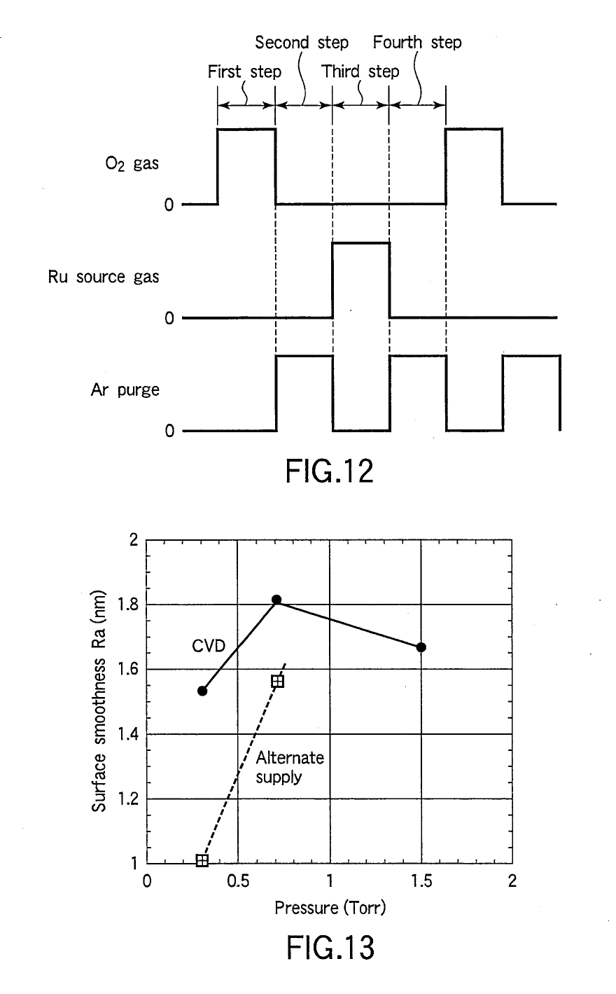

Then, gases are supplied to perform the film formation process. In this embodiment, an Ru compound used as an Ru source, such as a pentadienyl compound of Ru, e.g., 2,4-dimethylpentadienyl ethylcyclopentadienyl ruthenium, and O₂ gas are alternately supplied with Ar purge interposed therebetween. Specifically, as shown in FIG. 12, in a first step, the valves 66, 67, 71, and 72 are opened, so that O₂ gas used as a reaction gas and Ar gas used as a dilution gas are supplied from the oxygen gas supply source 53 and Ar gas supply source 68 through the showerhead 40 into the process chamber 1, while their flow rates are respectively controlled by the mass-flow controllers 65 and 70. Then, in a second step, the O₂ gas supply is stopped, and the Ar gas flow rate is increased, so that the interior of the process chamber 1 is purged. Then, in a third step, the Ar gas flow rate is decreased to the dilution gas level, and the valves 57 and 58 are opened, so that an Ru compound used as an Ru source, such as a pentadienyl compound of Ru, e.g., 2,4-dimethylpentadienyl ethylcyclopentadienyl ruthenium, is supplied into the vaporizer 54, while its flow rate is controlled by the liquid mass-flow controller 56. Further, the valves 62 and 63 are opened, so that Ar gas used as a carrier gas is supplied from the Ar gas supply source 59 into the vaporizer 54. With the operations described above, vapor of the pentadienyl compound of Ru is supplied through the showerhead 40 into the process chamber 1. Then, in a fourth step, the Ru source supply and carrier Ar supply are stopped, and the Ar gas flow rate is increased, so that the interior of the process chamber 1 is purged. The first step to fourth step described above are repeated a plurality of times.

In this embodiment, in the first step of mainly supplying the O₂ gas and dilution gas, the O₂ gas flow rate is preferably set to be about 100 to 500 mL/min (sccm), and the flow rate of Ar gas used as a dilution gas is preferably set to be 50 to 500 mL/min (sccm). In the third step of mainly supplying the Ru source gas and dilution gas, the Ru source gas flow rate is preferably set to be about 10 to 100 mL/min (sccm), and the flow rate of Ar gas used as a dilution gas is preferably set to be 10 to 300 mL/min (sccm). In the second step and fourth step of performing Ar gas purge, the Ar gas flow rate is preferably set to be 200 to 1,000 mL/min (sccm).

The time period of each first step is preferably set to be about 0.5 to 60 sec. The time period of each third step is also preferably set to be about 0.5 to 60 sec. The time period of the Ar gas purge in each of the second step and fourth step is preferably set to be about 0.5 to 120 sec. Further, the number of repetitions of these steps is suitably set to be about 10 to 200 times, although it depends on the supply gas flow rates and the thickness of a film to be formed.

In this embodiment, the gases are alternately supplied, but the relationship between the gases shown in FIG. 2 is effected as a whole, where the Ru source is a pentadienyl compound of Ru and the decomposing gas is O₂ gas. Accordingly, as in the first embodiment, it is preferable that the film formation temperature is set to be 350° C. or more and less than 500° C. and the partial pressure ratio α of O₂ gas/Ru source gas is set to be 0.01 or more and 3 or less, or that the film formation temperature is set to be 250° C. or more and less than 350° C. and the partial pressure ratio α of O₂ gas/Ru source gas is set to be 0.01 or more and 20 or less.

In order to further improve the step coverage, the value of (O₂ gas supply time×O₂ gas partial pressure)/(Ru source gas supply time×Ru source gas partial pressure) is preferably set to be 2 or more and 10 or less. If this value is lower than 2, the O₂ dose is insufficient, and the initial nuclei for film formation are low in number and discontinuous in supplying the Ru source gas. On the other hand, if this value exceeds 10, the Ru source gas dose is insufficient, and the initial nuclei for film formation are also low in number and discontinuous.

Also in this embodiment, CO gas is preferably further added to control the step coverage, as in the first embodiment. Where CO is added, the CO may be supplied along with O₂ gas in the first step of supplying the O₂ gas, so that the CO retards the reaction between the O₂ gas and Ru source gas and thereby helps non-reacted parts of the Ru source gas to reach the bottom of holes. Alternatively, the CO may be supplied in the purge step, so that the CO prevents non-reacted parts of the Ru source gas from causing a vapor phase reaction and/or from being adsorbed on the reaction surface. Alternatively, the CO may be supplied along with the Ru source gas in the third step.

In order to improve the surface smoothness of the Ru film, the pressure inside the process chamber during the film formation is preferably set to be as low as possible within a range that provides necessary step coverage. Specifically, the pressure is preferably set to be 6.65 Pa (0.05 Torr) or more and 133 Pa (1 Torr) or less. In the film formation using alternate supply according to this embodiment, rough grains can easily grow as compared to the continuous film formation according to the first embodiment, and, particularly, rough grains increase if the pressure exceeds 133 Pa (1 Torr). On the other hand, the film formation using alternate supply can provide better surface smoothness by setting the pressure to be lower, as compared to the continuous film formation. This matter is shown in FIG. 13. As shown in FIG. 13, in the case of the film formation using alternate supply, the surface smoothness becomes far better than that obtained by the continuous film formation (CVD), at a pressure of 0.3 Torr (40 Pa), but the surface smoothness is drastically deteriorated with an increase in the pressure.

In order to form an Ru film with low resistivity, this alternate supply is not so suitable. Specifically, where the film formation using alternate supply is performed, generation of initial nuclei for film formation tends to be insufficient in the third step of supplying the Ru source gas, and brings about an island shaped film, and so the resistivity of the film can be increased. In order to decrease the resistivity while taking advantage of the alternate supply, it is preferable that an Ru initial film with a small thickness is first formed by CVD continuous film formation using simultaneous supply and then a film is formed thereon by the film formation using alternate supply. Consequently, the initial film is formed of a continuous film, and the resistivity of the entire film is thereby decreased. In this case, the initial film preferably has a film thickness of about 2 to 10 nm. In reverse, it may be preferable that an Ru film is formed by first performing the film formation using alternate supply, and then performing the CVD continuous film formation using simultaneous supply. According to this method, the CVD film covers island shaped portions formed by the alternate supply, so that the resistivity is also decreased.

After the film formation process is performed as described above, the gate valve 38 is opened, and the semiconductor wafer W processed by the film formation is unloaded. After the film formation process is performed on a predetermined number of semiconductor wafers W, cleaning is performed inside the process chamber 1, as in the first embodiment.

Next, an explanation will be given of present examples, where film formation was actually performed in accordance with the second embodiment.

### Present Examples 21 to 24

In these examples, film formation was performed while the film formation temperature, pressure, and gas flow rate were set at different values, as shown in table 2. In the present example 21 that employed the film formation using alternate supply under conditions for obtaining preferable surface smoothness, the surface smoothness Ra took on a very good value of 1.01 nm. In the present example 22 using a higher pressure, the surface smoothness was 1.57 nm, which was poorer to some extent than that of the present example 21. In the present examples 23 and 24 that employed a combination of the alternate supply with CVD, the resistivity was 44 μΩ·cm in the present example 23 and it was 89.1 μΩ·cm in the present example 24.

TABLE 2

| | Film | | | Carrier | | Dilution | | | | | | | |
|---|---|---|---|---|---|---|---|---|---|---|---|---|---|
| | formation | | Ru source | Ar flow | O₂ flow | Ar flow | | Repetition | Film | | | | |
| | temperature | Pressure | flow rate | rate | rate | rate | Time | number | thickness | Resistivity | Ra | Coverage | |
| | ° C.) | (Torr) | (g/min) | (sccm) | (sccm) | (sccm) | (sec) | (cycles) | (nm) | (μΩ · cm) | (nm) | (%) | Remarks |
| Present | 320 | 0.3 | 0 | 0 | 200 | 100 | 10 | 40 | 14 | | 1.01 | 68 | |
| example | 320 | 0.3 | 0 | 0 | 0 | 300 | 5 | | | | | | |
| 21 | 320 | 0.3 | 0.1 | 103 | 0 | 172 | 5 | | | | | | |
| | 320 | 0.3 | 0 | 0 | 0 | 300 | 5 | | | | | | |
| Present | 320 | 1 | 0 | 0 | 200 | 100 | 10 | 40 | 21 | | 1.57 | 50 | |
| example | 320 | 1 | 0 | 0 | 0 | 300 | 5 | | | | | | |
| 22 | 320 | 1 | 0.1 | 103 | 0 | 172 | 5 | | | | | | |
| | 320 | 1 | 0 | 0 | 0 | 300 | 5 | | | | | | |
| Present | 320 | 0.3 | 0 | 0 | 200 | 100 | 10 | 40 | 36 | 44 | | 65 | Alternate |
| example | 320 | 0.3 | 0 | 0 | 0 | 300 | 5 | | | | | | supply + |
| 23 | 320 | 0.3 | 0.1 | 103 | 0 | 172 | 5 | | | | | | CVD |
| | 320 | 0.3 | 0 | 0 | 0 | 300 | 5 | | | | | | |
| | 320 | 0.3 | 0.1 | 103 | 55 | 122 | 300 | | | | | | |
| Present | 320 | 0.3 | 0.1 | 103 | 55 | 122 | 300 | | 25 | 89.1 | | 62 | CVD + |
| example | 320 | 0.3 | 0 | 0 | 200 | 100 | 10 | 40 | | | | | Alternate |
| 24 | 320 | 0.3 | 0 | 0 | 0 | 300 | 5 | | | | | | supply |
| | 320 | 0.3 | 0.1 | 103 | 0 | 172 | 5 | | | | | | |
| | 320 | 0.3 | 0 | 0 | 0 | 300 | 5 | | | | | | |

### Third Embodiment

In this embodiment, an explanation will be given of a case where the O₂ gas and Ru source gas are supplied while they are modulated, without a purge step interposed therebetween, unlike the film formation using alternate supply according to the second embodiment.

At first, as in the first embodiment, the gate valve 38 is opened, and a semiconductor wafer W is loaded through the transfer port 39 into the process chamber 1 and placed on the worktable 3. The semiconductor wafer W is heated by the worktable 3, which has been heated by heat rays emitted from the heating lamps 32 and transmitted through the transmission window 30. Then, the interior of the process chamber 1 is vacuum-exhausted by the vacuum pump (not shown) through the exhaust port 36 and exhaust line 37, to set the pressure inside the process chamber 1 at about 1 to 500 Pa. Further, at this time, the semiconductor wafer W is heated to a temperature of, e.g., 200 to 500° C.

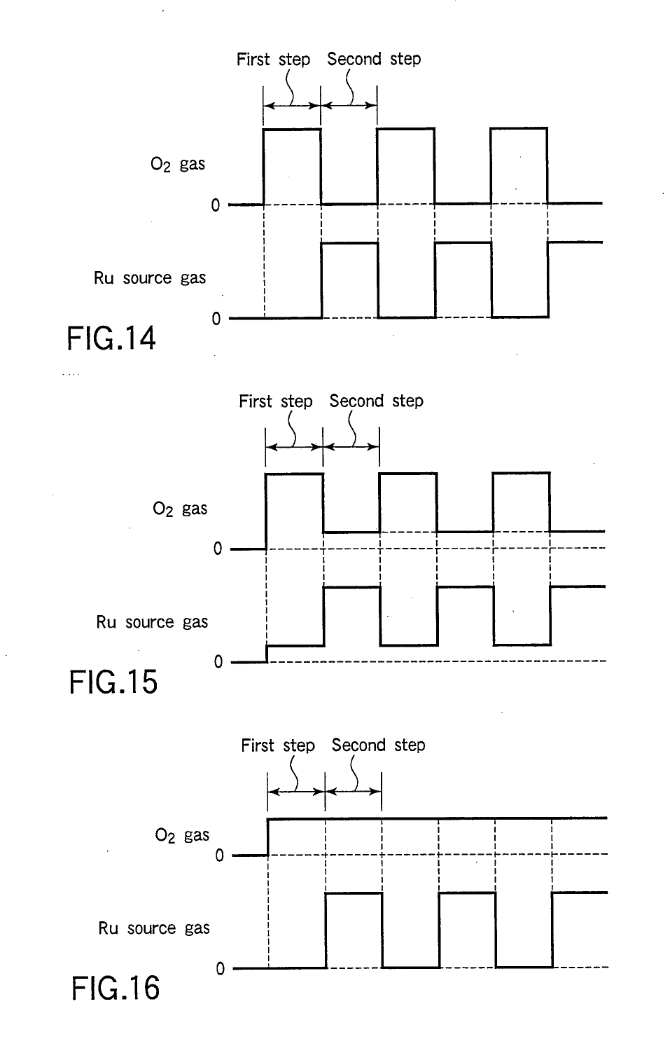

Then, gases are supplied to perform the film formation process. In this embodiment, the Ru source gas and O₂ gas are supplied while they are modulated. Specifically, as shown in FIG. 14, in a first step, the valves 66, 67, 71, and 72 are opened, so that O₂ gas used as a reaction gas and Ar gas used as a dilution gas are supplied from the oxygen gas supply source 53 and Ar gas supply source 68 through the showerhead 40 into the process chamber 1, while their flow rates are respectively controlled by the mass-flow controllers 65 and 70. Then, in a second step, while Ar used as a dilution gas is kept supplied, the O₂ gas supply is stopped, and the valves 57 and 58 are opened, so that an Ru compound used as an Ru source, such as a pentadienyl compound of Ru, e.g., 2,4-dimethylpentadienyl ethylcyclopentadienyl ruthenium, is supplied into the vaporizer 54, while its flow rate is controlled by the liquid mass-flow controller 56. Further, the valves 62 and 63 are opened, so that Ar gas used as a carrier gas is supplied from the Ar gas supply source 59 into the vaporizer 54. With the operations described above, vapor of the pentadienyl compound of Ru is supplied through the showerhead 40 into the process chamber 1. The first step and second step described above are repeated a plurality of times. At this time, as shown in FIG. 15, the first step may be arranged to supply the Ru source gas at a low flow rate without completely stopping it, and the second step may be arranged to supply the O₂ gas at a low flow rate without completely stopping it.

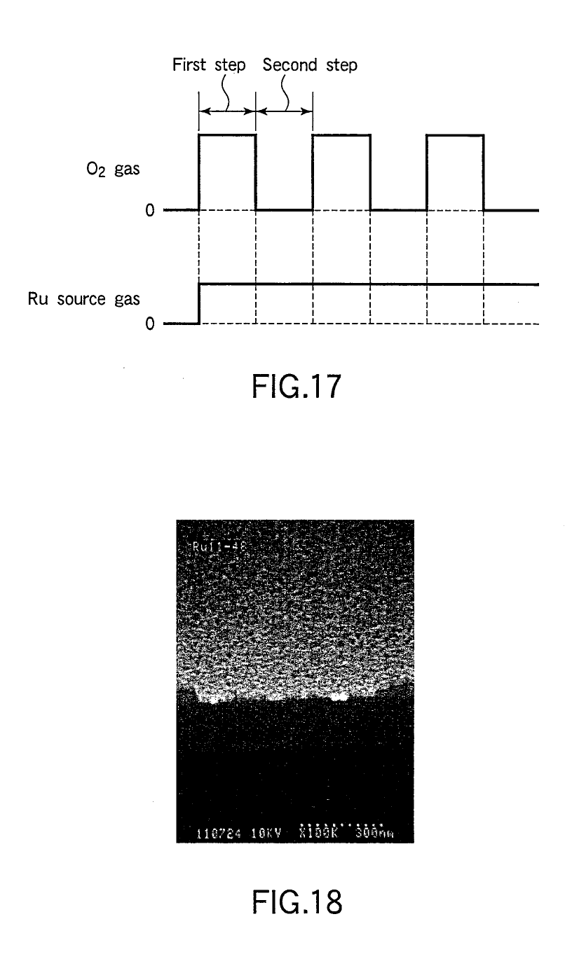

Alternatively, only one of the gases may be modulated, such that, as shown in FIG. 16, the O₂ gas is supplied at a constant flow rate, while the Ru source gas is modulated between the first step and second step, or, as shown in FIG. 17, the Ru source gas is supplied at a constant flow rate, while the O₂ gas is modulated between the first step and second step.

In this embodiment, the flow rate of a gas is modulated, but the relationship between the gases shown in FIG. 2 is effected as a whole, where the Ru source is a pentadienyl compound of Ru and the decomposing gas is O₂ gas. Accordingly, as in the first embodiment, it is preferable that the film formation temperature is set to be 350° C. or more and less than 500° C. and the partial pressure ratio α of O₂ gas/Ru source gas is set to be 0.01 or more and 3 or less, or that the film formation temperature is set to be 250° C. or more and less than 350° C. and the partial pressure ratio α of O₂ gas/Ru source gas is set to be 0.01 or more and 20 or less.

In this embodiment, as the partial pressure ratio α of O₂ gas/Ru source gas is higher, decomposition of the Ru source and precipitation of Ru tend to be caused. On the other hand, as α is lower, the decomposition and precipitation tend to be suppressed. Accordingly, where at least one of the Ru source gas and O₂ gas is modulated, a state in which the rate-determining factor is not dependent on supply is maintained, and so the step coverage is improved.

The gas supply according to this embodiment in which at least one of the Ru source gas and O₂ gas is modulated can be called alternate gas supply in a sense. A technique similar to this is disclosed in Jpn. Pat. Appln. KOKAI Publication No. 2003-226970, in which an Ru source and O₂ are used to form a film by an ALD method. This publication method is similar to this embodiment in that an Ru source gas and O₂ gas are alternately supplied. However, since atomic level layers are formed by alternately supplying the Ru source gas and O₂ gas, this publication method needs supply of a purge gas therebetween to remove the effect of the preceding gas. Accordingly, this publication method differs from this embodiment in which the preceding gas is not purged by a purge gas but remains while the subsequent gas is supplied. In other words, Jpn. Pat. Appln. KOKAI Publication No. 2003-226970 is conceived to enhance the reactivity by an ALD method of alternately laminating atomic level layers of Ru and O, and thus is based on a fixed idea in that a purge gas is inevitable to realize ALD. On the other hand, according to this embodiment, at least one of the Ru source gas and O₂ gas is modulated to control the reaction between the Ru source gas and O₂ gas without a purge step interposed therebetween, so that the step coverage is improved. Due to such a difference in principle, the technique disclosed in Jpn. Pat. Appln. KOKAI Publication No. 2003-226970 requires an unpractical number of repetitions, such as 2,000 times or more, to form a practically usable film. By contrast, this embodiment requires only several tens repetitions to form a practically usable film. In this respect, the technique of this embodiment is more advantageous than the technique disclosed in Jpn. Pat. Appln. KOKAI Publication No. 2003-226970.

In this embodiment, in the first step of mainly supplying the O₂ gas and dilution gas, the O₂ gas flow rate is preferably set to be about 100 to 500 mL/min (sccm), and the flow rate of Ar gas used as a dilution gas is preferably set to be 50 to 500 mL/min (sccm).

In this step, supply of a certain amount of Ru source may be permissible as described above, wherein the Ru source set at a flow rate of lower than 10 mL/min (sccm) does not damage the effect. In the second step of mainly supplying the Ru source gas and dilution gas, the Ru source gas flow rate is preferably set to be about 10 to 100 mL/min (sccm), and the flow rate of Ar gas used as a dilution gas is preferably set to be 10 to 200 mL/min (sccm). In this step, supply of a certain amount of O₂ gas may be permissible as described above, wherein the O₂ gas set at a flow rate of lower than 20 mL/min (sccm) does not damage the effect.

The time period of each first step is preferably set to be about 0.5 to 60 sec. The time period of each second step is also preferably set to be about 0.5 to 60 sec. Further, the number of repetitions of these steps is suitably set to be about 20 to 100 times, although it depends on the supply gas flow rates and the thickness of a film to be formed.

Also in this embodiment, CO gas is preferably further added to control the step coverage, as in the first embodiment. Where CO is added, the CO may be supplied along with O₂ gas in the first step of supplying the O₂ gas. Alternatively, the CO may be supplied along with the Ru source gas in the second step.

After the film formation process is performed as described above, the gate valve 38 is opened, and the semiconductor wafer W processed by the film formation is unloaded. After the film formation process is performed on a predetermined number of semiconductor wafers W, cleaning is performed inside the process chamber 1, as in the first embodiment.

In this embodiment, the Ru source gas and O₂ gas are suitably modulated as described above, and the step coverage is thereby remarkably improved. Accordingly, in this case, good step coverage can be obtained even where another Ru source, such as Ru(EtCp)₂ or Ru(Cp)₂ conventionally used, is used in place of the pentadienyl compound of Ru described above. Alternatively, in place of a combination of an Ru source and O₂ gas, another reaction sources may be used.

Next, an explanation will be given of present examples along with comparative examples, where film formation was actually performed in accordance with the third embodiment.

### Present Example 31

In the apparatus shown in FIG. 1, the lamp power was adjusted to set the temperature of the worktable at a film formation temperature of 384° C., and a 200-mm Si wafer was loaded by a transfer robot into the process chamber 1 to form an Ru film. The Ru source was 2,4-dimethylpentadienyl ethylcyclopentadienyl ruthenium. The 2,4-dimethylpentadienyl ethylcyclopentadienyl ruthenium was supplied from the mother tank (Ru compound supply source) 52 at a controlled flow rate through the liquid mass-flow controller (LMFC) 56 into the vaporizer 54 set at a temperature of 120° C. Then, it was vaporized by use of an Ar gas as a carrier gas in the vaporizer 54, and the vapor thus generated was supplied through the showerhead into the process chamber. Further, dilution Ar gas for diluting gas inside the process chamber, backside Ar gas for preventing gas from flowing around onto the backside of the wafer, and O₂ gas to react with the Ru source were supplied as other gases, as described above. The Ru source gas and O₂ gas were supplied while they are modulated between the step 1 and step 2. The conditions used at this time were set as follows.

Worktable temperature: 384° C.,

Pressure inside process chamber: 40 Pa, and

Backside Ar flow rate: 100 mL/min (sccm).

Step 1:
O₂ gas flow rate: 200 mL/min (sccm),
Dilution Ar flow rate: 100 mL/min (sccm), and
Time period: 5 sec.

Step 2:
Ru source flow rate: 16 mL/min (sccm)
Carrier Ar flow rate: 100 mL/min (sccm)
Dilution Ar flow rate: 181 mL/min (sccm), and
Time period: 10 sec.

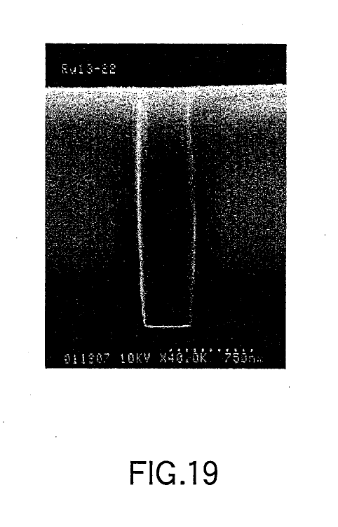

Number of repetitions of steps 1 and 2: 21 times. The Ru film thus formed had a thickness of 19.2 nm and a resistivity of 21.0 μΩ·cm. The surface state of the film was smooth, as shown in the scanning electron microscope (SEM) photograph of FIG. 18. Then, film formation was performed by repeating 41 times the steps 1 and 2 under the same conditions on a chip wafer with a hole pattern having a diameter of 0.5 μm and a depth of 2.2 μm. Consequently, the step coverage was as good as 90%, as shown in the SEM photograph of FIG. 19.

### Present Example 32

Further, film formation was performed by repeating 52 times the steps 1 and 2, under the same conditions as the present example 31 except that the conditions of the steps 1 and 2 were changed as shown below, on a chip wafer with a hole pattern having a diameter of 0.5 μm and a depth of 2.2 μm. Consequently, the step coverage was as good as 89%.

Step 1:
Ru source flow rate: 2 mL/min (sccm),
Carrier Ar flow rate: 100 mL/min (sccm),
O₂ gas flow rate: 200 mL/min (sccm),
Dilution Ar flow rate: 100 mL/min (sccm), and
Time period: 5 sec.

Step 2:
Ru source flow rate: 16 mL/min (sccm),
Carrier Ar flow rate: 100 mL/min (sccm),
O₂ gas flow rate: 2 mL/min (sccm),
Dilution Ar flow rate: 181 mL/min (sccm), and
Time period: 5 sec.

The present invention is not limited to the embodiments described above, and it may be modified in various manners.

For example, in the embodiments described above, the film formation apparatus is of the type that heats a target substrate by lamp heating, but it may be of the type that uses a resistant heating heater. In the embodiments described above, the target substrate is a semiconductor wafer, but it may be another substrate, such as an FPD glass substrate.

### INDUSTRIAL APPLICABILITY

A ruthenium film formation method according to the present invention can provide a film of high quality with good step coverage, and so the method can be preferably applied to formation of the electrodes of capacitors having an MIM structure, the gate electrodes of three-dimensional transistors, barrier/seed layers for Cu plating, and barrier/seed layers for Cu contact.

What is claimed is:

1. A ruthenium film formation method comprising: placing and heating a substrate inside a process chamber; supplying a ruthenium compound gas and a decomposing gas for decomposing this compound into the process chamber while periodically modulating at least one of flow rates of these gases, to form a plurality of steps having gas compositions different from each other, without purging an interior of the process chamber between these steps; and causing the gases to react with each other on the substrate thus heated, thereby forming a ruthenium film on the substrate.

2. The ruthenium film formation method according to claim 1, wherein the plurality of steps comprise a first step of supplying the decomposing gas into the process chamber and a second step of supplying the ruthenium compound gas into the process chamber, and the first and second steps are alternately and repeatedly performed without a step of purging an interior of the process chamber therebetween.

3. The ruthenium film formation method according to claim 1, wherein the plurality of steps comprise a first step of supplying a gas, which has a composition containing the decomposing gas in a relatively larger amount and the ruthenium compound gas in a relatively smaller amount, into the process chamber and a second step of supplying a gas, which has a composition containing the ruthenium compound gas in a relatively larger amount and the decomposing gas in a relatively smaller amount, into the process chamber, and the first and second steps are alternately and repeatedly performed without a step of purging an interior of the process chamber therebetween.

4. The ruthenium film formation method according to claim 1, wherein the decomposing gas is oxygen gas.

5. The ruthenium film formation method according to claim 1, wherein the ruthenium compound is a pentadienyl compound of ruthenium.

6. The ruthenium film formation method according to claim 1, wherein the ruthenium compound is a pentadienyl compound of ruthenium, and the decomposing gas is oxygen gas, and wherein a film formation temperature is set to be 350° C. or more and less than 500° C., and a partial pressure ratio α of the oxygen gas relative to the ruthenium compound gas is set to be 0.01 or more and 3 or less.

7. The ruthenium film formation method according to claim 1, wherein the ruthenium compound is a pentadienyl compound of ruthenium, and the decomposing gas is oxygen gas, and wherein a film formation temperature is set to be 250° C. or more and less than 350° C., and a partial pressure ratio α of the oxygen gas relative to the ruthenium compound gas is set to be 0.01 or more and 20 or less.

8. The ruthenium film formation method according to claim 1, wherein the pentadienyl compound of ruthenium is 2,4-dimethylpentadienyl ethylcyclopentadienyl ruthenium.

9. The ruthenium film formation method according to claim 1, wherein the method comprises supplying CO into the process chamber in film formation.
